(19) United States
(12) Patent Application Publication
(10) Pub. No.: US 2007/0053156 A1
(43) Pub. Date: Mar. 8, 2007

(54) Housing cup for an electronic component with integrated cooling body

(76) Inventor: Lothar Regenfus, Neunkirchen (DE)

Correspondence Address: BRINKS HOFER GILSON & LIONE, P.O. BOX 10395, CHICAGO, IL, 60610, US

(21) Appl. No.: 10/577,413

(22) PCT Filed: Oct. 28, 2004
(86) PCT No.: PCT/EP04/52685

§ 371 Date: Apr. 26, 2006

(30) Foreign Application Priority Data
Oct. 31, 2003 (DE) 10350896.1

(51) Int. Cl. H05K 7/20

(52) U.S. Cl. 361/688

(57) ABSTRACT

A housing of an electronic component with an integrated cooling body is provided. The cup base of the housing is formed as a cooling body. The cooling body and the housing cup are formed integrally by an extrusion method.

### RELATED APPLICATIONS

The present patent document is a continuation of PCT Application Serial No. PCT/EP2004/052685, filed Oct. 28, 2004, designating the United States, which is hereby incorporated by reference.

### BACKGROUND

1. Field

The present embodiments relate to a housing for an electronic component comprising a housing cup with an integrated cooling body.

2. Discussion of Related Art

During the operation of electronic components, a considerable amount of power can be lost in the form of heat. Higher losses cause increased heat stress. Increased heat stress can shorten the service life of the electronic component. To prevent heat stress, heat must be dissipated via the housing of the electronic component. The ability of the housing to dissipate heat substantially determines the service life, the specific field of use, and the electrical design of the electronic component.

By improving heat dissipation features, the current-carrying capacity or the allowance of higher ambient temperatures can be increased. Electronic components are sometimes oversized to reduce heating. However, oversizing electronic components is disadvantageous because of the increased material required to make the parts larger.

It is also possible to connect the electronic components to a plurality of identical electronic components in order to lower the load of each individual component and increase the cooling surface. For example, capacitors can be connected in parallel to lower the load of each capacitor. However, the parallel connection creates increased number of electronic components and is disadvantageous because of the higher production costs and the increased effort of assembly.

To reduce the heat of a housing a cooling body is often secured to the housing of the electronic component by a screwing method. A cooling body is designed to efficiently dissipate the heat created by the electronic component. The heat transfer between the electronic component and the cooling body can be improved with use of heat-conducting foil, known as “Thermopads”, as an intermediate layer, or by means of corresponding heat-conducting pastes. However, securing a cooling body to the housings of electronic components also involves increased effort of assembly.

German Patent DE 198 17 493 C1 discloses an electrolyte capacitor whose housing is provided with a number of cooling fins. The housing of the capacitor is embodied as a cast aluminum part.

Housings for electronic components are often formed in a cylindrical form. These housings, depending on their internal construction and the type of electronic component, dissipate heat via the cylindrical base. Electronic components with a cylindrical base have a reduced heat-conducting capacity in the radial direction because of the internal construction. In a cylindrical component, an air gap, which can be up to several millimeters wide, between the electronic component and the housing can act as an internal heat resistor and create heat stress. In addition, heat dissipation via the cup base can be reduced because electrical contact between the cup base and the electronic component are not sufficient for proper heat dissipation without additional provisions. For example, in a capacitor, the cathode foil must be made to protrude from the lower end of the coil in order to greatly improve the heat connection between the coil and the cup base on one side. Thus, it is of importance to dissipate heat for components with reduced heat-conducting capacity.

### SUMMARY

The present embodiments are directed to a housing cup for an electronic component with an integrated cooling body which may obviate one or more of problems due to the limitations and disadvantages of the related art.

A housing cup for an electronic component is formed with a cup base. The cup base is formed into a cooling body that is integral with the housing cup, such as by extrusion. Integrating the cooling body with the housing cup, allows the current-carrying capacity of the electronic component, compared to a corresponding electronic component with a smooth housing wall, to be increased substantially. For example, the current-carrying capacity may be increased by more than 100%, depending on the type of electronic component. No substantial additional costs occur in producing the housing cup because the cooling body is stamped out jointly in the same work step with the stamping of the housing cup. The cooling action of the housing cup is also enhanced by producing it by extrusion. Because of the compaction of the housing material and because of the material structure developed in the course of the flow of material, the heat-conducting capacity of the housing cup is increased.

In one embodiment, the cooling body includes a number of protrusions, which protrude from the cup base essentially in the axial direction of the housing cup. These protrusions may be formed in pin-like, prism-like or lamination-like form. Various other forms of protrusions can be used in combination.

The basic shape of the housing cup is essentially cylindrical. The cylindrical shape of the housing cup has proved advantageous, particularly because of its excellent pressure stability.

In another embodiment of the housing, the cooling body or at least one of its axial protrusions can be used as a mechanical guide element. This embodiment is particularly beneficial when a plurality of electronic components is connected to one another. This element can advantageously be employed in arrangements with larger electronic components that have to be connected to one another to form multicomponent assemblies, where because of the particular way the product is used, increased resistance to shock and jarring is necessary.

The cooling body may be cooled directly or indirectly by means of a fluid. With direct cooling, the cooling body is bathed directly by the fluid, for example, with deionized water. In the indirect variant, the element used for mechanically guiding the electronic component has fluid flowing through it, or the cooling body itself is embodied such that it can be connected to cooling elements, for example, with cooling hoses or cooling tubules. This embodiment maximizes heat removal from the housing surface.

An electrolyte capacitor having an embodiment of the housing cup as described above is one type of capacitor. In the capacitor, higher losses occur because of alternating voltage or voltages of increasing waviness, because of the resultant alternating current or the resultant current of increased waviness, and because of the comparatively higher substitute series resistance. The consumption of the service life of the capacitor and the attendant worsening of its electrical parameters (capacitance) are higher and are directly dependent on the heat development in the capacitor. Because of the internal construction of the component, the heat removal via the cup base plays a decisive role in the capacitor because, in the radial direction, the heat-conducting capacity is limited due to its particular construction. The air gap, which may be several millimeters wide, between the coil and the side wall acts as an additional heat resistor.

In another embodiment, the capacitor is cooled whenever the capacitor winding, comprising two capacitor foils and a dielectric, is wound in such a way that a capacitor foil protrudes from the capacitor winding base. The cup base formed into the cooling body is electrically connected directly to the protruding capacitor foil.

Compared to electrically contacting the capacitor foil with a smooth cup base without an additionally formed cooling body, or a cup base formed into the cooling body without direct electrical contacting of the capacitor foil to the cup base, the heat emission capacity and thus the alternating current load and/or service life of the capacitor can be increased further by multiple times. By disposing the cooling body on the cup based, especially effective heat dissipation is attained, since on the cup base, the thermal contact between the housing cup and the capacitor winding of the capacitor is especially good.

A method will be described that forms the housing cup of the electronic component, such as by extrusion. In the course of the pressing operation of the housing cup, an integrated cooling body is formed into the cup base. The production method is based on a method of using a matrix. The matrix is provided in a base region with the negative shape of the cooling body to be made.

The advantages are particularly that the current-carrying capacity of the electronic component is increased substantially because of the improvement in heat dissipation to the housing surface and by improving the heat removal from the housing surface, without entailing significant additional expenses for producing the component. The higher current-carrying capacity of the electronic component makes a cost reduction possible in making electronic circuits, especially since the number of electronic components to be connected to one another can be reduced. For the same service life, the electronic component equipped according to the invention is capable of carrying higher current than a conventional one with a smooth cup wall. Conversely, if the load on the electronic component remains the same, a longer service life is attained. The housing cup is also easy to manipulate, especially since the additional effort for attaching cooling bodies can be eliminated.

The increased heat removal from the housing surface is assured by the integration of a cooling body into the cup base. Preferably in multicomponent assemblies, the heat transport is positively influenced by directly contacting the cooling body with separate air- or fluid-cooled elements. Still another substantial increase in heat dissipation is attained by the direct electrical contacting of the capacitor winding with the cup base.

### BRIEF DESCRIPTION OF THE DRAWINGS

Exemplary embodiments of the invention will be described further detail below in conjunction with the drawings. Shown in the drawings are:

FIG. 1 is a schematic cross section of a housing for an electronic component with a housing cup and a cooling body integrated into the cup base;

FIG. 2 shows a top view of a cup base and the cooling body that is provided with pin-like protrusions;

FIG. 3 shows, in a view corresponding to FIG. 2, an alternative embodiment of the cooling body, in which the protrusions are embodied in lamination-like form;

FIG. 4 shows a cylindrical capacitor winding formed such that the capacitor foil protrudes from the capacitor winding base;

FIG. 5 is a schematic cross section of a capacitor comprising a housing as shown in FIG. 1 and a capacitor winding as shown in FIG. 4;

FIG. 6 shows a multicomponent assembly for capacitors with indirect cooling.

### DETAILED DESCRIPTION

Reference will be made in detail to the preferred embodiments, examples of which are illustrated in the accompanied drawings. Wherever possible, elements corresponding to one another are identified by the same reference numerals in all the drawings.

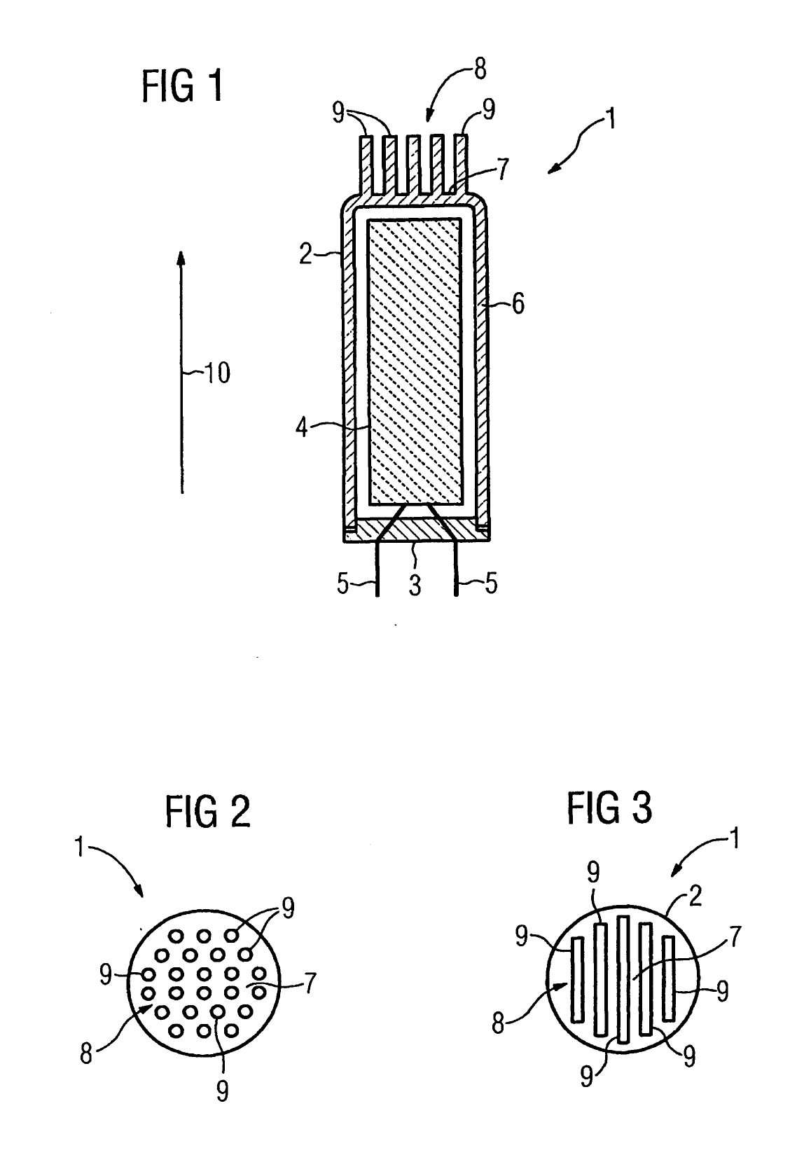

As shown in FIG. 1, an electronic component housing 1 includes a cylindrical housing cup 2 which is closed off with a housing cap 3. In the interior of the housing formed by the housing cup 2 and the housing cap 3 is the electronic component 4 which is electrically contacted by two contact leads 5 (wire terminals) that pass through the housing cap 3.

The housing cup 2 has a tubular side wall 6. The open end of the housing cup 2 is closed off by a cup base 7 integrated with the side wall 6. The cup base 7 and the housing cap 3 are on the opposite face ends of the housing cup 2. The cup base 7 forms the bottom face of a cooling body 8 and is integrated with the housing cup 2. The cooling body 8 includes a number of protrusions 9 which protrude from the outer surface of the cup base 7 in the axial direction 10 of the housing cup 2 and are spaced apart from one another.

FIGS. 2 and 3, in a view counter to the axial direction 10 of the cup base 7, show two alternative embodiments of the protrusions 9. In FIG. 2, the protrusions 9 are embodied in pin-like form. In FIG. 3, the protrusions 9 have the shape of laminations. In both versions, the cross section through the electronic component housing 1 corresponds to the view in FIG. 1. The protrusions 9 may also be embodied as prism-like (not shown).

The housing cup 2 which includes the cooling body 8, is produced in a single step by means of extrusion. This technique produces a smooth housing cup for a electrolyte capacitor. When forming the cooling body 8, the production method is modified such that the matrix of a pressing device, used for producing the housing cup 2, is provided in a base region with the negative shape of the cooling body 8 to be made. During the pressing operation of the housing cup 2, the cooling body 8 is then automatically molded with it.

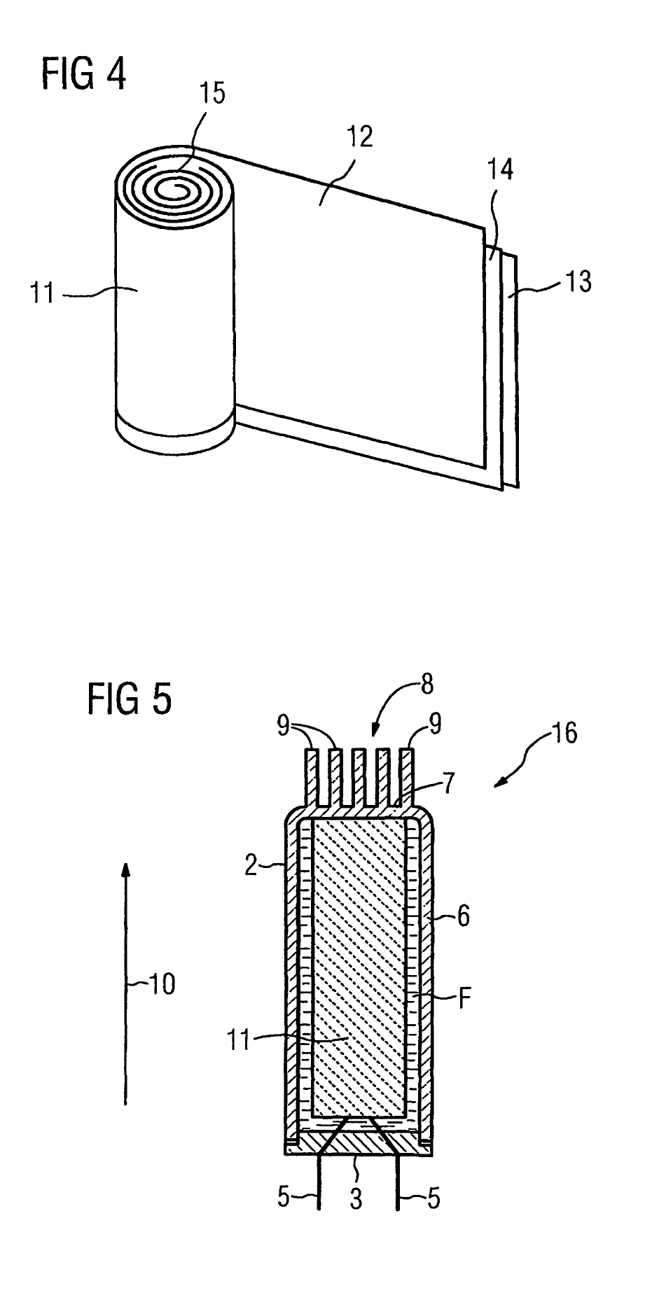

FIG. 4 shows a cylindrical capacitor winding 15. The capacitor winding 15 is created by winding up a material composed of at least three layers. One layer forms the cathode foil 12; another layer forms a dielectric made of electrolyte-saturated paper 13; and a third layer forms the anode foil 14. The various layers are located one above the other but not with projection precision. The capacitor winding 15 is formed such that the cathode foil 12, on a capacitor winding base, has an offset from the paper layer and anode foil. The electrolyte-saturated intermediate paper layer 14 insulates the cathode foil 12 and the anode foil 13 from one another.

As shown in FIG. 5, the capacitor 16 includes a cylindrical housing cup 2. The cylindrical shape of the housing cup has proved advantageous, particularly because of its excellent pressure stability. The open end of the cylindrical housing cup 2 is closed off with a housing cap 3. Located in the interior of the housing formed by the housing cup 2 and the housing cap 3 is the capacitor winding 11, which is electrically contacted by two contact leads 5 which pass through the housing cap 3. The interior of the housing 2 and the housing cap 3 is also filled with an electrolytic fluid F. The capacitor winding base 15, with its protruding capacitor foil, directly contacts the inside of the cup base 7 electrically.

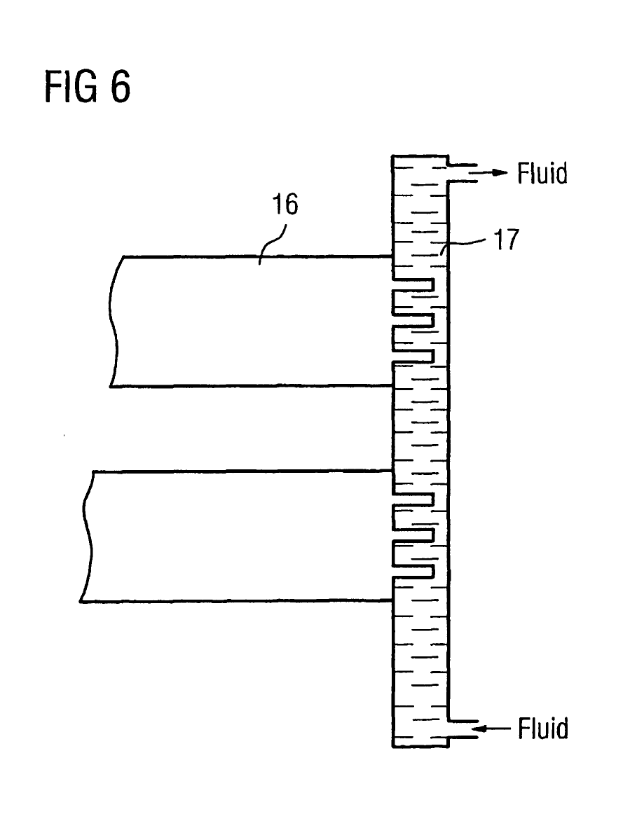

FIG. 6 shows an arrangement of capacitors 16 according to the invention. The cooling bodies 8 of the capacitors 16 are connected in a heat-conducting fashion to a mechanical fastening element 17. The mechanical fastening element 17 comprises heat-conducting material and has conduits through which a fluid flows as a cooling fluid. This embodiment is particularly beneficial when a plurality of electronic components is connected to one another. This embodiment can advantageously be employed in arrangements with larger electronic components that have to be connected to one another to form multicomponent assemblies, where because of the particular way the product is used, increased resistance to shock and jarring is necessary.

In an exemplary embodiment (not shown), the cooling body 8 of a capacitor 16 may also be embodied such that it is connected directly to a cooling hose or cooling tube. The cooling body may for instance have a bore, through which a cooling hose or cooling tube is passed, or it may be embodied such that a cooling hose or cooling tube can be fastened to it. With direct cooling, the cooling body is bathed directly by the fluid, for example, with deionized water. In the indirect variant, the element used for mechanically guiding the electronic component has fluid flowing through it, or the cooling body itself is embodied such that it can be connected to cooling elements, for example, with cooling hoses or cooling tubules. This embodiment maximizes heat removal from the housing surface.

No substantial additional costs occur in producing the housing cup because the cooling body is formed in the same work step with the forming of the housing cup. The cooling action of the housing cup is also enhanced when produced by pressing. Because of the compaction of the housing material and because of the material structure developed in the course of the flow of material, the heat-conducting capacity of the housing cup is favorably influenced.

In another preferred embodiment, an electrolyte capacitor having a housing cup as described above is used. An electrolyte capacitor normally has a higher loss because of alternating voltage or voltages of increasing waviness, because of the resultant alternating current or the resultant current of increased waviness, and because of the comparatively higher substitute series resistance. The consumption of the service life of the capacitor and the reduction of its capacitance are higher and are directly dependent on the heat development in the capacitor. Because of the internal construction of the component, the heat removal via the cup base plays a decisive role in the capacitor because the heat-conducting capacity is limited because of its particular construction, for example, the air gap, between the coil and the side wall acts as an additional heat resistor and increases heat stress.

While the invention has been described above by reference to various embodiments, it should be understood that many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention.

1. A housing for an electronic component comprises a housing cup formed with a cup base
wherein the cup base is formed into a cooling body integrated with the housing cup.

2. The housing of claim 1,
wherein the cooling body includes a number of protrusions protruding substantially in the axial direction from the cup base.

3. The housing of claim 1,
wherein at least one protrusions from the cooling body is formed in a pin-like, prism-like or lamination-like form.

4. The housing of claim 1,
wherein the housing cup is substantially cylindrical.

5. The housing of claim 2,
wherein at least one axial protrusion of the cooling body is used for mechanical guidance.

6. The housing of claim 5,
wherein the cooling body is cooled directly or indirectly by a fluid.

7. A capacitor comprising an electrolyte capacitor having a housing cup formed with a cup base, wherein the cup base is formed into a cooling body integrated with the housing cup.

8. The capacitor of claim 7, having a capacitor winding comprising:
first and second capacitor foils; and
a dielectric,
wherein the capacitor winding is wound such that either the first or second capacitor foil protrudes out of the capacitor winding base, and
wherein the cup base electrically contacts the protruding capacitor foil.

9. A method for producing a housing, the method comprising:
using a matrix during a pressing operation of a housing cup, wherein the matrix is provided in a base region with the negative shape of the cooling body; and
automatically molding the cooling body with the housing cup.

10. The method of claim 9, wherein the matrix includes a number of protrusions protruding in the axial direction from the base region.

11. The housing of claim 1, wherein at least one axial protrusion of the cooling body is used for mechanical guidance.

12. The housing of claim 1, wherein the cooling body is cooled directly or indirectly by a fluid.

13. The capacitor of claim 7 wherein the cooling body includes a number of protrusions protruding substantially in the axial direction from the cup base.

14. The capacitor of claim 7, wherein the housing cup is substantially cylindrical.

15. The capacitor of claim 7, wherein at least one axial protrusion of the cooling body is used for mechanical guidance.

16. The capacitor of claim 7, wherein the cooling body is cooled directly or indirectly by a fluid.

17. The method of claim 10, further comprising:
using at least one of the axial protrusions as a mechanical guide.

18. The method of claim 9, further comprising:
cooling the cooling body with fluid.
